(19) United States
(12) Patent Application Publication
(10) Pub. No.: US 2007/0210450 A1
(43) Pub. Date: Sep. 13, 2007

(54) Method of forming a bump and a connector structure having the bump

(76) Inventors: Woo-Jin Jang, Seoul (KR); Kwang-Myeon Park, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 11/708,496

(22) Filed: Feb. 21, 2007

(30) Foreign Application Priority Data
Mar. 13, 2006 (KR) 10-2006-22924

(51) Int. Cl. H01L 23/48; H01L 23/52

(52) U.S. Cl. 257/734

(57) ABSTRACT

A bump may be formed by forming a diffusion barrier layer pattern over a substrate having a conductive pad; forming a seed layer over the substrate having the diffusion barrier layer pattern and the conductive pad; forming a conductive bump over the seed layer; and patterning the seed layer using the conductive bump as an etching mask.

### BACKGROUND OF THE INVENTION

1. Field of the Invention

The invention relates to methods of manufacturing a bump and a connector structure having the bump. More particularly, the invention relates to methods of manufacturing a bump that electrically connects a semiconductor chip with a board, and a connector structure including the bump.

2. Description of the Related Art

Generally, a semiconductor device is manufactured through a semiconductor chip manufacturing process that forms a semiconductor chip with an integrated circuit on a silicon substrate, an electrical die sorting (EDS) process that electrically tests and sorts the semiconductor chip, a packaging process that protects the semiconductor chip, and a mounting process that mounts a package onto a board.

To manufacture a semiconductor device having high performance and high integration rate, it is important that the whole manufacturing processes be supported by an advanced packaging technology because the size of the semiconductor device, the heat emission capacity, the electrical characteristics, the reliability, the cost, etc. may greatly fluctuate according to the packaging technology.

Packaging technology has been sequentially developed using package types such as a single inline package (SIP), a dual inline package (DIP), a quad flat package (QFP), a ball grid array (BGA) and a chip scale package (CSP). Recently, a stacked chip scale package (SCSP) and a wafer level chip scale package (WLCSP) have been developed along with an improvement of the CSP.

In the above-mentioned recent packaging technologies, a flip-chip mounting method is utilized. The flip-chip mounting method forms a conductive bump on an unpacked semiconductor chip and directly combines the bump with an electrode formed on the board to thus electrically connect the semiconductor chip with the board. The flip-chip mounting method has an advantage of making the package have a smaller mounting area and have a thinner mounting height compared with the related art wire bonding method.

FIG. 1 illustrates a cross-sectional view of the conductive bump of the related art flip-chip in package (FCIP).

FIG. 1 illustrates that a conductive bump 50 is required to combine a semiconductor chip 10 with the board in the flip-chip mounting method.

The conductive bump 50 electrically connects a pad 20 of the semiconductor chip 10 with the electrode of the board, and the conductive bump 50 is formed on the pad 20.

The conductive bump 50 is generally formed from a metal different from that of the pad 20. Particularly, the conductive bump 50 is formed from a metal such as solder or gold, and the pad 20 is formed from a metal such as aluminum or copper, thereby rendering difficult the formation of the conductive bump 50 directly on the pad 20. To solve this problem, an under bump metallurgy (UBM) is formed between the pad 20 and the conductive bump 50. Through the UBM, the conductive bump 50 is formed on the pad 20.

A related art UBM 40 includes a seed layer pattern 41, a diffusion barrier layer pattern 43 and an adhesion layer pattern (not shown). The adhesion layer pattern is formed from a material similar to that of the diffusion barrier layer pattern 43. The UBM 40 may thus include the seed layer pattern 41 and the diffusion barrier layer pattern 43. The UBM 40 has the seed layer pattern 41 and the diffusion barrier layer pattern 43 being integrally formed, as is illustrated in FIG. 1. The UBM 40 is formed as follows.

A sacrificial layer forms on the semiconductor chip 10 having the pad 20. The sacrificial layer is etched to form a sacrificial layer pattern 30 that partially exposes an upper portion of the pad 20. A diffusion barrier layer and a seed layer are formed on the sacrificial layer pattern 30 and the pad 20. A photoresist pattern is deposited on the diffusion barrier layer and the seed layer, which partially exposes an upper portion of the pad. The conductive bump 50 is formed on the upper portion of the pad using the photoresist pattern, and the photoresist pattern is then removed. Then, the diffusion barrier layer and the seed layer are etched using the conductive bump 50 as an etching mask. As a result, the diffusion barrier layer pattern 43 and the seed layer pattern 41 are formed on the pad 20 extending from the pad 20 to the sacrificial layer pattern 30.

The diffusion barrier layer pattern 43 necessarily closely seals an upper portion of the pad 20 to prevent the conductive bump 50 from diffusing into the pad 20. However, according to the related art method of forming the bump, the diffusion barrier layer pattern 43 may be excessively etched under a lower portion of the conductive bump 50 so that the diffusion barrier layer pattern 43 fails to serve as a diffusion barrier layer. This is called an undercut of a diffusion barrier layer pattern.

The undercut of the diffusion barrier layer pattern is caused by forming the diffusion barrier layer pattern 43 and the seed layer pattern 41 by etching the diffusion barrier layer and the seed layer using a wet etching process. Particularly, the seed layer is etched to form the seed layer pattern 41 by a wet etching process using a first etchant. The seed layer is isotropically etched. The seed layer under the conductive bump 50 may hence be etched, and thus form the seed layer pattern 41 having a width smaller than that of the conductive bump 50 under the conductive bump 50.

The diffusion barrier layer is etched to form the diffusion barrier layer pattern 43 by a wet etching process using a second etchant. The diffusion barrier layer is isotropically etched. The diffusion barrier layer under the seed layer pattern 41 may hence be etched to thereby form the diffusion barrier layer pattern 43 having a width smaller than that of the seed layer pattern 41.

According to the related art method of forming the bump, the seed layer pattern 41 is formed to have a width smaller than that of the conductive bump 50, and the diffusion barrier layer pattern 43 is formed to have a width much smaller than that of the seed layer pattern 41. As a result, a space 45 between the conductive bump 50 and the pad 20 generates such that the pad 20 is damaged by the second etchant flowing into the space 45.

The semiconductor chip 10 receives and sends electrical signals through the pad 20. If the pad 20 is damaged, the semiconductor chip 10 fails to receive and send electrical signals correctly, thereby causing malfunction or failure of the semiconductor device. Therefore, preventing the second etchant from flowing into the pad 20 is important. However, the related art method fails to prevent the second etchant from flowing into the pad 20 because of the above-mentioned problems.

The diffusion barrier layer pattern 43 contacts the pad 20 having a proper contact area. When the contact area between the diffusion barrier layer pattern 43 and the pad 20 decreases, the working reliability of the semiconductor deteriorates.

To prevent the deterioration of the working reliability of the semiconductor, related art methods are used to increase the size of the conductive bump 50 and a process margin for the conductive bump 50. However, this technical fix is against the miniaturization trend in the semiconductor industry, which strives to make features smaller and to achieve higher integration.

The seed layer pattern 41 and the diffusion barrier layer pattern 43 require proper thicknesses between the conductive bump 50 and the pad 20 to serve as the UBM. According to the related art method, the seed layer pattern 41 and the diffusion barrier layer pattern 43 are patterned using a wet etching process to thereby make difficult the control of the thicknesses of the seed layer pattern 41 and the diffusion barrier layer pattern 43.

As discussed above, semiconductor device development pursues high integration and high performance. Thus, the price of the semiconductor chip and the semiconductor device including the semiconductor chip continuously increases. When the semiconductor chip and the semiconductor device are damaged using related art technology, a considerable amount of financial burden and time loss inevitably followed.

### SUMMARY OF THE INVENTION

The present invention is therefore directed to a bump on a semiconductor chip that substantially overcomes one or more of the problems due to the limitations and disadvantages of the related art, and a connector structure including the bump.

At least one of the above and other features and advantages of the invention may be realized by providing a bump that includes forming a diffusion barrier layer pattern over a substrate having a conductive pad; forming a seed layer over the substrate having the diffusion barrier layer pattern and the conductive pad; forming a conductive bump over the seed layer; and patterning the seed layer using the conductive bump as an etching mask.

At least one of the above and other features and advantages of the invention may be realized by providing a connector structure that includes a substrate; a conductive pad over the substrate; an anti-reflective layer pattern over edge portions of the conductive pad; a diffusion barrier layer over the conductive pad and the anti-reflective layer pattern, a sacrificial layer pattern separating and being in direct contact with the anti-reflection layer pattern and the diffusion barrier layer such that there may be no open space between the anti-reflection layer pattern and the diffusion barrier layer; a seed layer pattern over the diffusion barrier layer; and a bump over the seed layer pattern.

### BRIEF DESCRIPTION OF THE DRAWINGS

The above and other features and advantages of the invention will become more apparent to those of ordinary skill in the art by describing in detail example embodiments thereof with reference to the attached drawings in which:

FIG. 1 illustrates a cross-sectional view of a related art flip-chip package;

FIGS. 2 to 12 illustrate sequential cross-sectional views of a method of forming a bump in accordance with an embodiment of the invention; and

FIGS. 13 to 21 illustrate sequential cross-sectional views of a method of forming a bump in accordance with another embodiment of the invention.

### DETAILED DESCRIPTION OF THE INVENTION

Korean Patent Application No. 10-2006-22924 filed on Mar. 13, 2006, in the Korean Intellectual Property Office, and entitled: “Method of Forming a Bump,” is incorporated by reference herein in its entirety.

The invention will now be described more fully hereinafter with reference to the accompanying drawings, in which example embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Similar reference numerals refer to similar elements throughout.

FIGS. 2 to 12 illustrate sequential cross-sectional views of a method of forming a bump in accordance with an example embodiment of the invention.

FIG. 2 illustrates a semiconductor substrate 110 having a conductive pad 120. An integrated circuit electrically connected to the conductive pad 120 is formed over the semiconductor substrate 110.

The conductive pad 120 includes a conductive metal such as aluminum, copper, silver, gold or alloys of these materials.

An upper portion of the conductive pad 120 is partially exposed through a sacrificial layer and an anti-reflection layer. Particularly, the anti-reflection layer and the sacrificial layer are formed on the substrate 110 having the conductive pad 120. The anti-reflection layer and the sacrificial layer are patterned to partially expose the upper portion of the conductive pad 120. The conductive pad 120 is sealed by the sacrificial layer pattern 135 and an anti-reflection layer pattern 125, and the upper portion of the conductive pad 120 is partially opened by the sacrificial layer pattern 135 and the anti-reflection layer pattern 125.

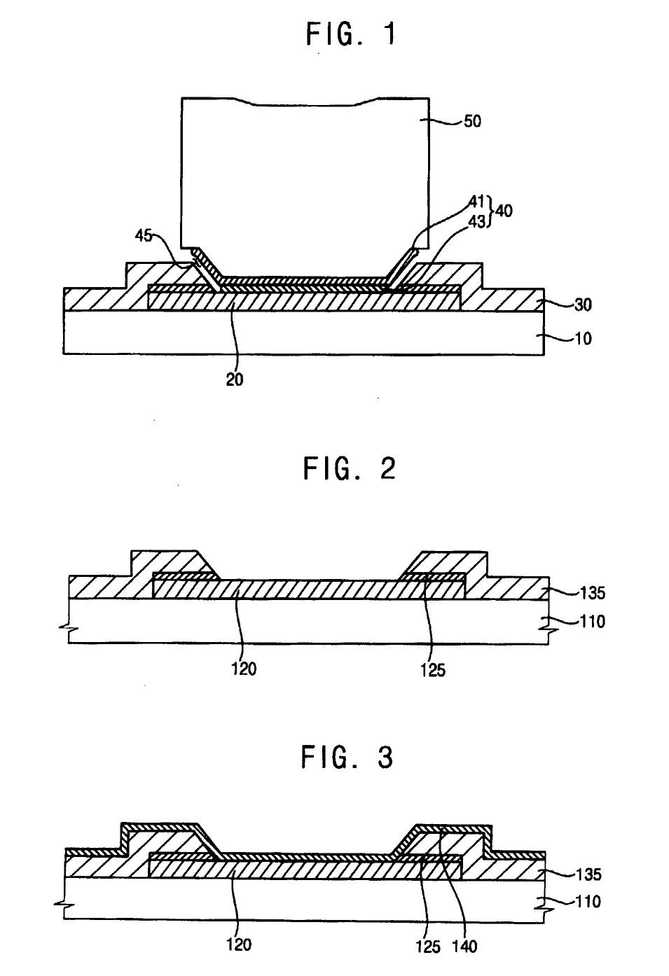

The material and method of forming the sacrificial layer pattern 135 and the anti-reflection layer pattern 125 are substantially the same as those of the related art technology described with reference to FIG. 1.

FIG. 3 illustrates a diffusion barrier layer 140 being formed over the semiconductor substrate 110 having the conductive pad 120.

The diffusion barrier layer 140 is formed from a material having a low electrical resistivity, and having a good adhesion with the conductive pad 120 and the sacrificial layer pattern 135. The diffusion barrier layer 140 is formed from a material being capable of preventing a bump from diffusing into the conductive pad 120. For example, the diffusion barrier layer 140 may include chromium, titanium-tungsten, nickel, etc. However, the diffusion barrier layer 140 is not restricted to these materials, and any appropriate material may be used.

The diffusion barrier layer 140 may serve as an adhesion layer as well as a diffusion barrier layer. The diffusion barrier layer 140 may form as a single layer to serve as both an adhesion layer and a diffusion barrier layer. Alternatively, the diffusion barrier layer 140 may be formed as different layers respectively including an adhesion layer and a diffusion layer. For example, the diffusion barrier layer 140 may include a chromium-copper bilayer, a titanium-tungsten-copper trilayer, an aluminum-nickel bilayer, etc. The diffusion barrier layer may be formed as multi-layers including at least three layers or more.

The above-described diffusion barrier layer 140 may be formed using various processes. For example, the diffusion barrier layer 140 may be formed by an evaporation process, a sputtering process, a plating process, a screen printing process, an electroless plating process, etc.

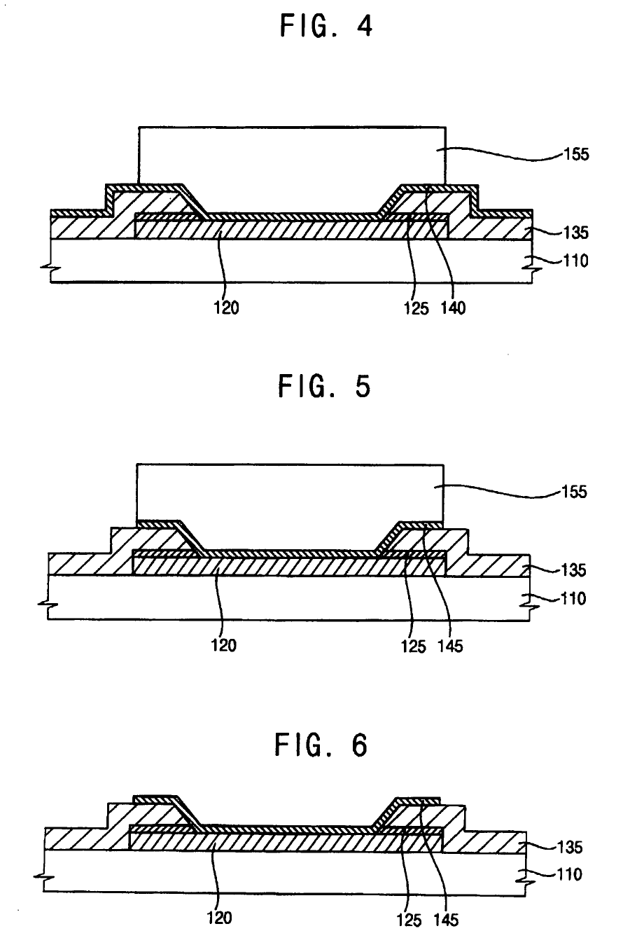

In FIG. 4, a first photoresist layer may be formed on the diffusion barrier layer 140. The photoresist can be a positive or a negative photoresist. The first photoresist layer may be patterned to form a first photoresist pattern 155 on the diffusion barrier layer 140. The first photoresist pattern 155 may have a width substantially greater than that of the conductive pad 120.

FIG. 5 illustrates that the diffusion barrier layer 140 may then be patterned to form a diffusion barrier layer pattern 145 using the first photoresist pattern 155 as an etching mask. The diffusion barrier layer pattern 145 forms under the first photoresist pattern 155 by partially removing the diffusion barrier layer 140 so as to leave a portion of the diffusion barrier layer 140 only under the first photoresist pattern 155.

The diffusion barrier layer 140 may be formed by a dry etching process such as a plasma etching process. An etchant gas for etching the diffusion barrier layer 140 in a dry etching process may be determined by a material included in the diffusion barrier layer 140. For example, a gas including fluorine, chlorine, etc., may be used as the etchant gas.

Various kinds of materials and etchant gases may be used to form the diffusion barrier layer. Although all of them are not particularly described hereinafter, those skilled in the art will readily appreciate them.

In the dry etching process, the diffusion barrier layer 140 may be substantially vertically etched so that the diffusion barrier layer pattern 145 has substantially the same width as that of the first photoresist pattern 155. The diffusion barrier layer pattern 145 may have substantially vertically etched side walls.

No undercut generates in the diffusion barrier layer pattern 145 formed under the first photoresist pattern 155, and the diffusion barrier layer pattern 145 accordingly closely seals the sacrificial layer pattern 135 and the anti-reflection layer pattern 125 such that no open space or gap may be formed.

The diffusion barrier layer pattern 145 as well as a seed layer pattern may serve as under bump metallurgies (UBM). The diffusion barrier layer pattern 145 may serve as a first UBM and the seed layer pattern may serve as a second UBM. The diffusion barrier layer pattern 145 may serve as the first UBM by closely sealing the sacrificial layer pattern 135 and the anti-reflection layer pattern 125.

In the related art method, a thickness of the diffusion barrier layer pattern 145 is controlled by a wet etching process of the diffusion barrier layer 140 that is formed thicker than a final designated thickness of the diffusion barrier layer pattern 145. However, the diffusion barrier layer pattern 145 may not form to have a precise thickness because of the characteristics of the wet etching process.

In contrast, an example embodiment of the present invention may have the thickness of the diffusion barrier layer 140 being substantially the same as that of the diffusion barrier layer pattern 145. Therefore, when the diffusion barrier layer 140 forms to have a precise thickness, the diffusion barrier layer pattern 145 also forms to have a precise thickness. Thus, the diffusion barrier 140 may properly serve as both an adhesion layer and a diffusion barrier layer.

Referring to FIG. 6, the diffusion barrier layer pattern 145 is exposed by removing the first photoresist pattern 155. In this case, the diffusion barrier layer pattern 145 maintains a close seal with the sacrificial layer pattern 135 and the anti-reflection layer pattern 125.

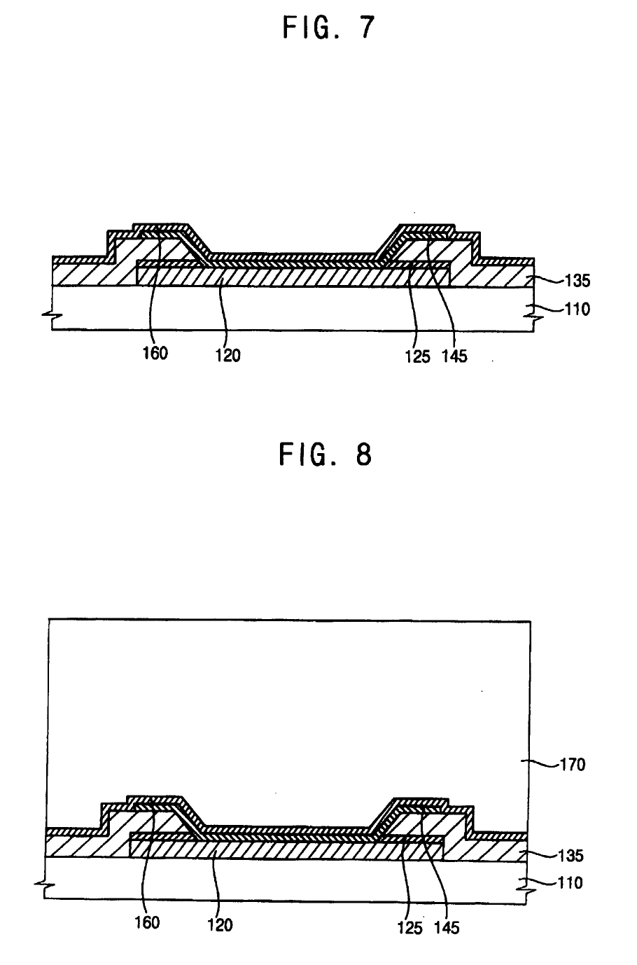

In FIG. 7, a seed layer 160 is formed over the semiconductor substrate 110 having the diffusion barrier layer pattern 145.

The seed layer 160 is formed from a material having good adhesion and good wettability with a bump that is described below. In addition, the seed layer 160 is formed from a material having good adhesion with the diffusion barrier layer pattern 145 and having good electrical conductivity. For example, the seed layer 160 may include copper, gold, palladium, etc. In an example embodiment of the present invention, the seed layer 160 may be formed from a material that is substantially the same as that of the bump to thus have good adhesion and wettability with the bump.

In an example embodiment of the present invention, the seed layer 160 may be formed as multi-layers. For example, the seed layer 160 may include a copper-gold bilayer, a copper-palladium bilayer, a gold-palladium bilayer, etc.

The seed layer 160 is patterned to be a seed layer pattern by using either a dry etching process or a wet etching process. When the seed layer 160 is patterned by the dry etching process, the seed layer 160 may be formed to have a thickness that is substantially the same as a final designated thickness of the seed layer pattern. In contrast, when the seed layer 160 is patterned by the wet etching process, the seed layer 160 necessarily forms to have a thickness greater than the final designated thickness of the seed layer pattern. Thus, the thickness of the seed layer may be determined according to a patterning process of the seed layer that is subsequentially performed.

FIG. 8 shows a second photoresist layer 170 that is formed over the seed layer 160.

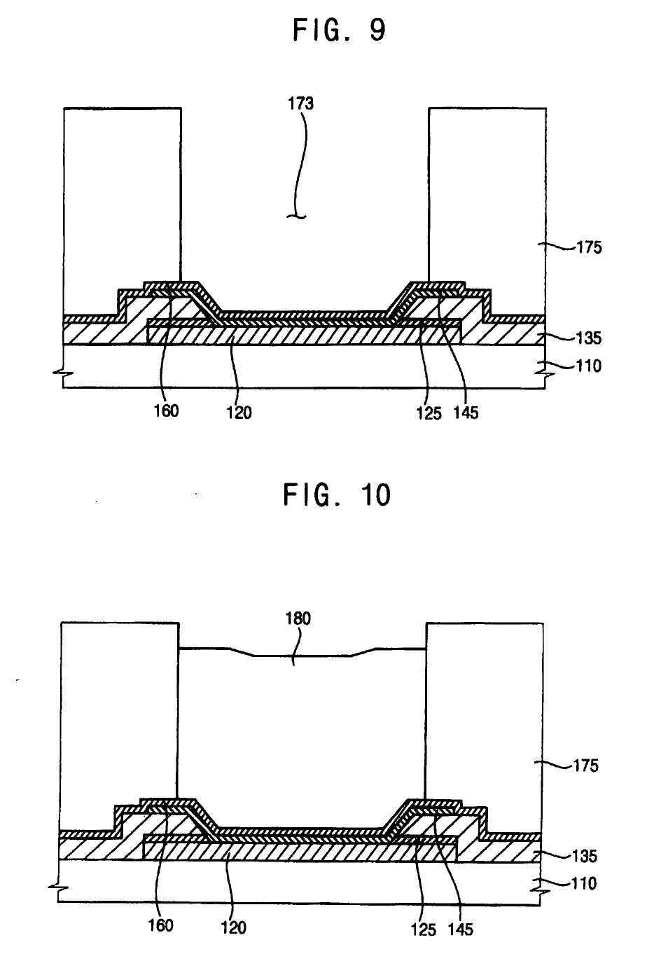

In FIG. 9, a second photoresist pattern 175 is formed over the seed layer 160 by patterning the second photoresist layer 170. The second photoresist pattern 175 has an opening 173 that exposes an upper part of the conductive pad 120.

The opening 173 is formed from an upper face to a lower face of the second photoresist layer 170. The opening 173 partially exposes the upper part of the conductive pad 120 such that a portion of the seed layer 160 is exposed. However, the upper face of the conductive pad 120 is not exposed by the opening 173.

Referring to FIG. 10, a bump 180 is formed over the conductive pad 120 by filling the opening 173 with a conductive material such as gold, copper, solder, etc. The solder can be a lead based or an indium based solder.

The bump 180 is a conductive protrusion that electrically connects the semiconductor substrate 120 with a board. In addition, the semiconductor substrate 120 may be loaded on the board in a flip-chip type or in a tap type by the conductive bump 180.

In an example embodiment of the present invention, the bump 180 may be formed from a material that is substantially the same as that of the seed layer 160, so that the bump 180 has good adhesion and good wettability with the seed layer 160. For example, the bump 180 may include gold, solder, copper, etc. In an example embodiment of the present invention, the bump 180 may include gold that has good electrical conductivity and has relatively easy to controllability of its size.

As described above, the bump 180 may form by using a process such as an evaporation process, an electroplating process, a screen printing process, a ball loading process, a super-juffit process, a stud process, etc. The bump 180 that is formed by the electroplating process is capable of using a material having a low melting point and less cost.

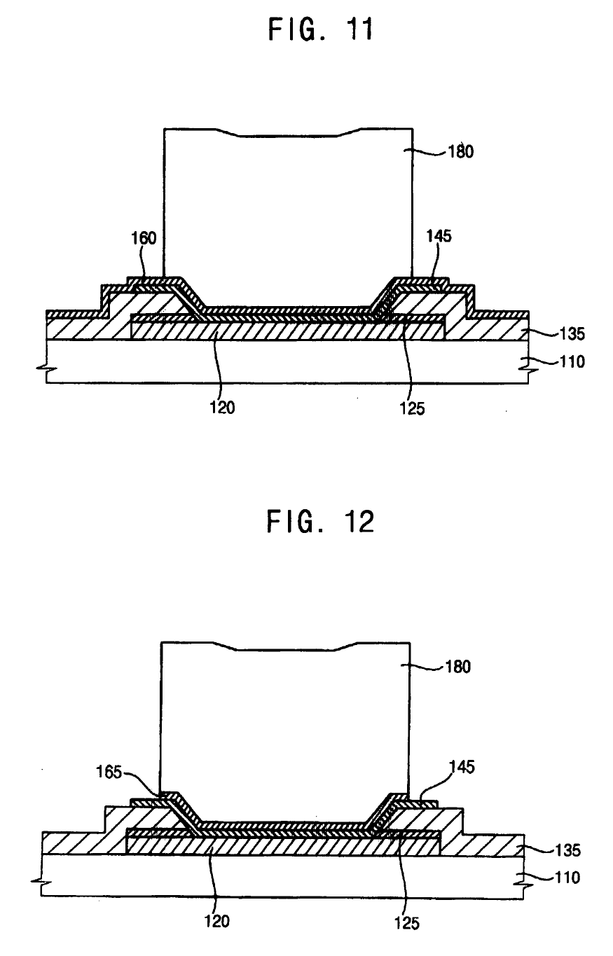

Referring to FIG. 11, the bump 180 is exposed over the seed layer 160 by removing the second photoresist pattern 175. The diffusion barrier layer pattern 145 maintains a close seal with the sacrificial layer pattern 135 and the anti-reflection layer pattern 125.

In FIG. 12, the seed layer 160 may be patterned by using the bump 180 as an etching mask. The seed layer 160 may be removed except for a portion of the seed layer 160 under the bump 180 to form a seed layer pattern 165 so that the seed layer 160 remains only under the bump 180. The seed layer pattern 165 serves as an UBM together with the diffusion barrier layer pattern 145.

The seed layer 160 may be patterned by using either a dry etching process or a wet etching process. In an example embodiment of the present invention, the seed layer 160 may be patterned by the wet etching process, which is more advantageous than the dry etching process in terms of having less processing time and less manufacturing cost. Hereinafter, a method of patterning the seed layer 160 by the wet etching process will be described.

The wet etching etchant of the seed layer 160 may be determined according to the materials included in the seed layer 160 and the diffusion barrier layer pattern 145. Particularly, when the seed layer 160 is etched by the wet etching process, an etchant that has an etch rate of the diffusion barrier layer 145 that is lower than the seed layer 160 may be used. Thus, an etchant having a large etch selectivity between the seed layer 160 and the diffusion barrier layer 145 is preferred. For example, when the seed layer 160 includes titanium-tungsten and the diffusion barrier layer pattern includes gold, hydrogen peroxide may be used as the etchant. Also, other etchant materials can be added to the hydrogen peroxide, such as ammonia, citric acid, mineral acids or fluorinated compounds.

Various kinds of materials and various etching gases having a large etch selectivity with these materials may be used to form the seed layer 160 and the diffusion barrier layer 145. Though all of them are not particularly described hereinafter, those skilled in the art will readily appreciate them.

When the seed layer 160 is patterned, the diffusion barrier layer pattern 145 is virtually intact by being hardly etched or not etched at all. Therefore, an undercut, which is the etched portion of the diffusion barrier layer pattern 145 under the bump 180, rarely generates.

The conductive pad 120 is substantially entirely sealed by the diffusion barrier layer pattern 145 and the sacrificial layer pattern 135. The etchant does not flow into the conductive pad 120 such that the conductive pad 120 is protected from the etchant. That is, no open space or gap may be formed.

In an example embodiment of the present invention, after the diffusion barrier layer pattern 145 is formed, the bump 180 may be reflowed by a thermal treatment so that the bump 180 may transform. For example, when the bump 180, including solder, is reflowed, the bump 180 transforms to have a ball shape by the surface tension. When the bump 180 including gold is reflowed, the bump 180 transforms to have a square pillar shape.

In the related art method, the diffusion barrier layer 140 is patterned by a wet etching process. Controlling the thickness of the diffusion barrier layer is thus difficult, and an undercut of the diffusion barrier layer pattern 145 generates. The diffusion barrier layer pattern 145 thus fails to serve as the UBM, and the conductive pad 120 is damaged by the etchant.

To solve the above-mentioned problems, in the related art method, the diffusion barrier layer pattern 145 and the seed layer pattern 165 are formed to have wide widths. The bump 180 is formed to have a wide width as well as to correspond to the width of the diffusion barrier layer pattern 145 and the seed pattern 165. Thus, the bump 180 may not be narrow because of the undercut of the diffusion barrier layer 140.

In accordance with the above-mentioned example embodiment of the present invention, the above-described difficulties may be effectively alleviated by etching the diffusion barrier layer 140 using a dry etching process.

FIGS. 13 to 21 illustrate cross-sectional views sequentially illustrating a method of forming a bump in accordance with example embodiments of the invention.

FIG. 13 illustrates a conductive pad 220 being formed on a semiconductor substrate 210 by a damascene method. The conductive pad 220 forms in an upper portion of the semiconductor substrate 210. The conductive pad 220 may be electrically connected with integrated circuits (not shown) formed over the semiconductor substrate 210.

The conductive pad 220 may include a conductive material such as a titanium, tungsten, aluminum, copper, silver, gold, platinum, alloys of these metals, etc.

A sacrificial layer may be formed on the semiconductor substrate 210 having the conductive pad 220. The sacrificial layer may be patterned to form a sacrificial layer pattern 235 that partially exposes an upper face of the conductive pad 220.

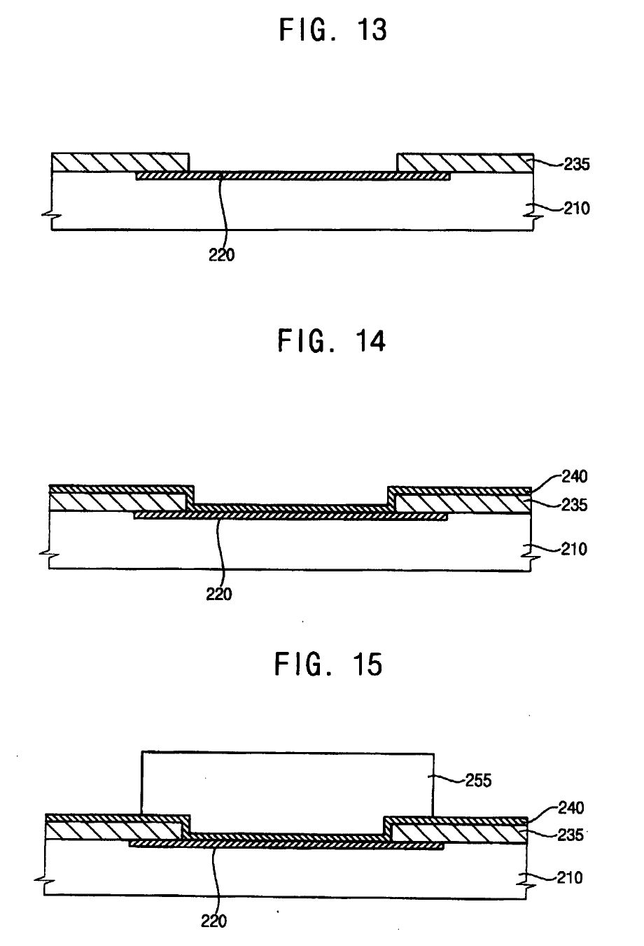

FIG. 14 illustrates a diffusion barrier layer 240 that may form over the semiconductor substrate 210 bearing the sacrificial layer pattern 235 and the conductive pad 220.

The diffusion barrier layer 240 may be formed from a material having low electrical resistivity and good adhesion with the conductive pad 220 and the sacrificial layer pattern 235. In addition, the diffusion barrier layer 240 may be formed from a material that is capable of effectively preventing a bump from diffusing into the conductive pad 220. For example, the diffusion barrier layer 240 may include chromium, titanium-tungsten, nickel, etc.

The diffusion barrier layer 240 may be formed as multi-layers. For example, the diffusion barrier layer 240 may include a chromium-copper bilayer, a titanium-tungsten-copper trilayer, an aluminum-nickel bilayer, etc. The diffusion barrier layer may be formed as multi-layers including at least three layers.

Referring to FIG. 15, a first photoresist layer may be formed over the diffusion barrier layer 240. The first photoresist layer may be patterned to form a first photoresist pattern 255 on the diffusion barrier layer 240. Here, the first photoresist pattern 255 may have a width greater or less than that of the conductive pad 220.

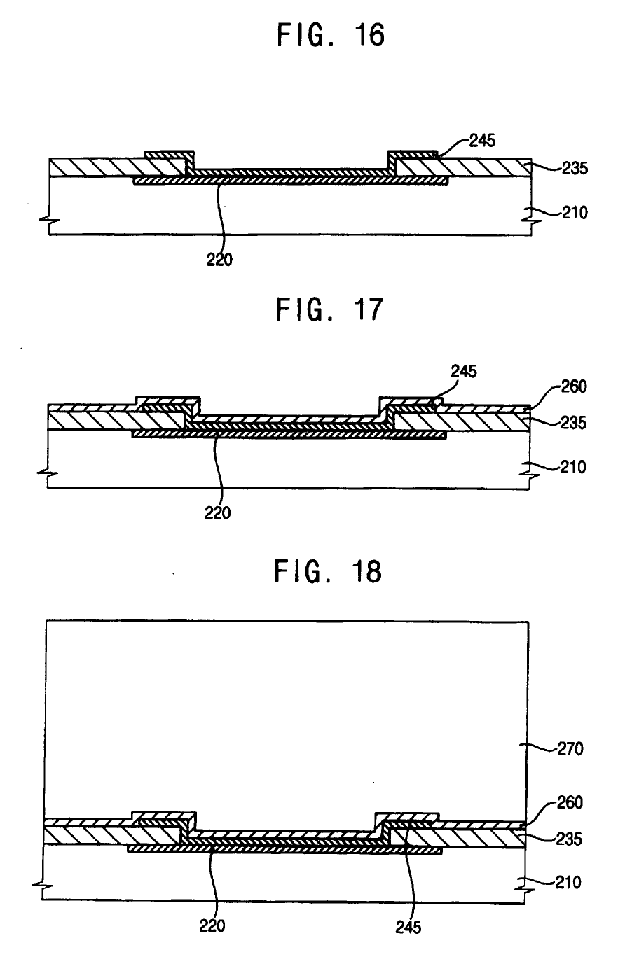

In FIG. 16, the diffusion barrier layer 240 may be patterned to form a diffusion barrier layer pattern 245 using the first photoresist pattern 255 as an etching mask. The diffusion barrier layer pattern 245 forms only under the first photoresist pattern 255 by partially removing a portion of the diffusion barrier layer 240 excluding portions under the first photoresist pattern 255.

The diffusion barrier layer 240 may be patterned by a dry etching process. An etchant gas for etching the diffusion barrier layer 240 in a dry etching process may be determined according to the material of the diffusion barrier layer 240.

In the dry etching process, the diffusion barrier layer 240 may be substantially vertically etched so that the diffusion barrier layer pattern 245 may have substantially the same width as that of the first photoresist pattern 255. The diffusion barrier layer pattern 245 may have substantially vertically etched side walls, i.e., walls at an approximately 90 degree angle in relation to the substrate 210.

An undercut fails to generate in the diffusion barrier layer pattern 245 formed under the first photoresist pattern 255 so that the diffusion barrier layer pattern 245 closely seals the sacrificial layer pattern 235 and the anti-reflection layer pattern 225. That is, no open space or gap may be formed.

The diffusion barrier layer pattern 245 may serve as an under bump metallurgy (UBM) together with a seed layer pattern described below. The diffusion barrier layer pattern 245 may serve as a first UBM, and the seed layer pattern may serve as a second UBM. The diffusion barrier layer pattern 245 may properly serve as the first UBM by closely sealing the sacrificial layer pattern 135 and the anti-reflection layer pattern 125.

In an example embodiment of the present invention, the thickness of the diffusion barrier layer 240 may be substantially the same as that of the diffusion barrier layer pattern 245. Therefore, when the diffusion barrier layer 240 is formed to have a precise thickness, the diffusion barrier layer pattern 245 also forms to have a precise thickness. Thus, the diffusion barrier 240 may properly serve as both an adhesion layer and a diffusion barrier layer.

After the diffusion barrier layer pattern 245 is formed, the barrier layer pattern 245 may be exposed by removing the first photoresist pattern diffusion 255. FIG. 17 illustrates a seed layer 260 formed on the semiconductor substrate 210 having the diffusion barrier layer pattern 245.

The seed layer 260 may be formed from a material having good adhesion and good wettability with a bump. In addition, the seed layer 260 may be formed from a material having good electrical conductivity and good adhesion with the diffusion barrier layer pattern 245. For example, the seed layer 260 may include copper, gold, palladium, etc.

In an example embodiment of the present invention, the seed layer 260 may be formed from a material that is substantially the same as that of a bump so that the seed layer 260 has good adhesion and wettability with the bump.

In FIG. 18, a second photoresist layer 270 may be formed over the seed layer 260.

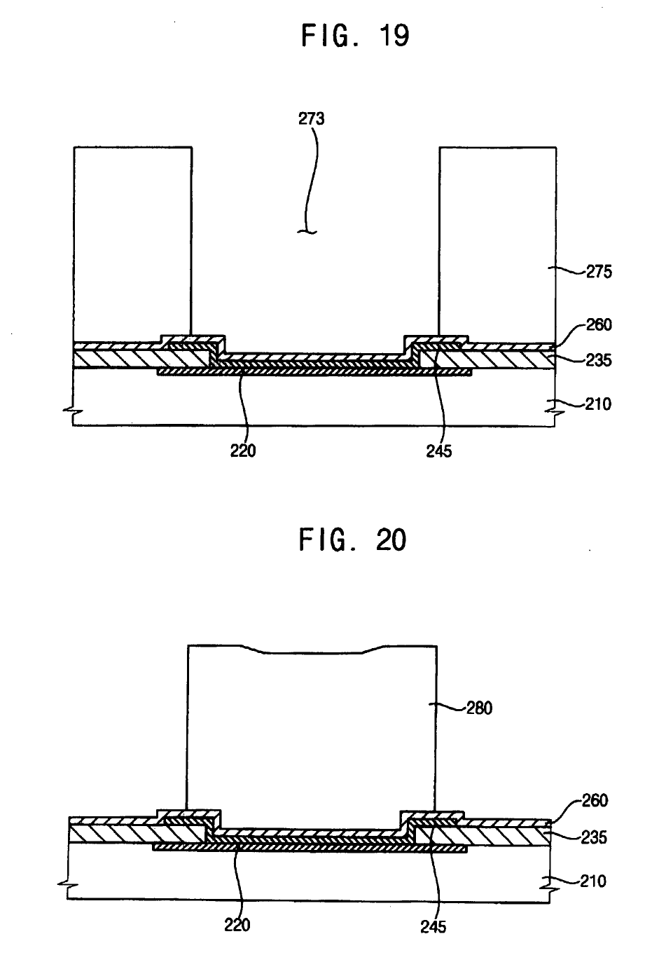

Referring to FIG. 19, the second photoresist pattern 275 forms over the seed layer 260 by patterning the second photoresist layer 270. The second photoresist pattern 275 may have an opening 273 that exposes an upper part of the conductive pad 220.

The opening 273 forms from an upper face to a lower face of the second photoresist layer 270. The opening 273 exposes the upper part of the conductive pad 220. However, the upper face of the conductive pad 220 may not be exposed through the opening 273, but rather a face of the seed layer 260 may be exposed.

In FIG. 20, a bump 280 may form over the conductive pad 220 by filling the opening 273 with a conductive material such as gold, copper, silver, solder, etc. The solder may be lead based or indium based.

The bump 280 may be formed from a material that is substantially the same as that of the seed layer 260 so that the bump 280 has good adhesion and good wettability with the seed layer 260. For example, the bump 280 may include gold, copper, silver, solder, etc. For example, the bump 280 includes gold, which has good electrical conductivity and has relatively easy size control.

As mentioned above, the bump 280 may be formed by a process such as an evaporation process, an electroplating process, a screen printing process, a ball loading process, a super-juffit process, a stud process, etc. In an example embodiment of the present invention, the bump 280 may be formed by the electroplating process that costs less and is capable of using a material having a low melting point.

After the bump 280 is formed, the bump 280 may be exposed on the seed layer 260 by removing the second photoresist pattern 275.

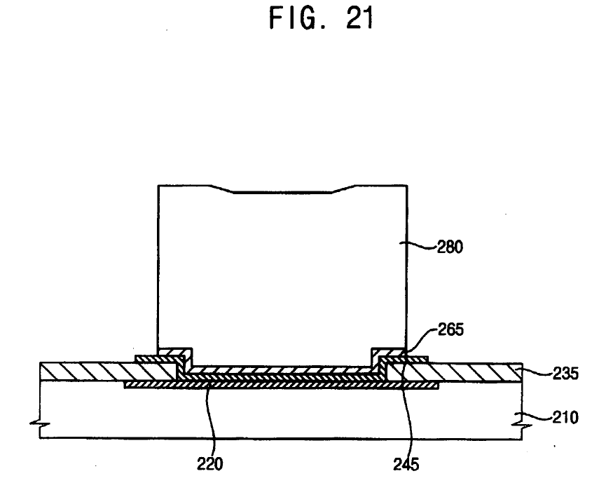

Referring to FIG. 21, the seed layer 260 may be patterned by using the bump 280 as an etching mask. Portions of the seed layer 260, excluding a portion under the bump 280, may be removed to form a seed layer pattern 265 so that the seed layer 260 remains only under the bump 280. The seed layer pattern 265 serves as the UBM together with the diffusion barrier layer pattern 245.

The seed layer 260 may be patterned by a dry etching process or a wet etching process. In an example embodiment of the present invention, the seed layer 260 may be patterned by the wet etching process, which is more advantageous than the dry etching process in terms of having less processing time and lower manufacturing cost.

A wet etching etchant of the seed layer 260 may be determined according to the materials of the seed layer 260 and the diffusion barrier layer pattern 245. Particularly, when the seed layer 260 is etched by the wet etching process, an etchant is selected that has an etch rate of the diffusion barrier layer 245 that is lower than that of the seed layer 265. Thus, the etchant having a large etch selectivity between the seed layer 260 and the diffusion barrier layer 145 may be preferred.

When the seed layer 260 is patterned, the diffusion barrier layer pattern 245 may remain essentially intact by being scarcely etched or not etched at all. Therefore, an undercut or gap, which is the etched portion of the diffusion barrier layer pattern 245 under the bump 280, may be scarcely generated or not generated at all.

The conductive pad 220 may be substantially entirely sealed by the diffusion barrier layer pattern 245 and the sacrificial layer pattern 235. As a result, the etchant does not flow into the conductive pad 220. Therefore, the conductive pad 220 may be protected from the etchant.

According to the above-mentioned example embodiments of the present invention, the thickness of the diffusion barrier layer pattern 145 and 245 may be easily controlled. An undercut or gap of the diffusion barrier layer pattern 145 and 245 may not be generated, so that the diffusion barrier layer 145 and 245 properly serves as the UBM. As a result, the bump 180 and 280 may be formed and disposed to have a relatively small width, and a flip-chip package having good electrical and structural characteristics may finally be manufactured.

According to the invention, an undercut of a first UBM may be effectively prevented by patterning the first UBM prior to patterning a second UBM. Therefore, the size of an entire UBM may be reduced and characteristics such as conductivity, adhesion, diffusion barrier property, wetting, etc., may be improved. The invention also reduces the bump size so that a package guaranteeing stable functionality may be manufactured.

Example embodiments of the invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the invention as set forth in the following claims.

What is claimed is:

1. A method of forming a bump, comprising:
forming a diffusion barrier layer pattern over a substrate having a conductive pad;
forming a seed layer over the substrate having the diffusion barrier layer pattern and the conductive pad;
forming a conductive bump over the seed layer; and
patterning the seed layer using the conductive bump as an etching mask.

2. The method as claimed in claim 1, wherein forming the diffusion barrier layer pattern comprises:
forming a diffusion barrier layer over the substrate having the conductive pad;
forming a photoresist pattern over the diffusion barrier layer positioned over the conductive pad;
patterning the diffusion barrier layer using the photoresist pattern as an etching mask; and
removing the photoresist pattern.

3. The method as claimed in claim 2, wherein the patterning the diffusion barrier layer is performed by a dry etching process.

4. The method as claimed in claim 1, wherein the patterning the seed layer is performed by a wet etching process.

5. The method as claimed in claim 4, wherein in the wet etching process, an etch rate of the seed layer is substantially greater than that of the diffusion barrier layer.

6. The method as claimed in claim 1, wherein forming the conductive bump comprises:
forming a photoresist pattern over the seed layer, the photoresist pattern exposing an upper portion of the conductive pad;
filling the exposed upper portion of the conductive pad with the conductive bump; and
removing the photoresist pattern.

7. The method as claimed in claim 1, further comprising forming an anti-reflection layer pattern over the conductive pad.

8. The method as claimed in claim 7, further comprising forming a sacrificial layer pattern over the substrate exposing an upper portion of the conductive pad before forming the diffusion barrier layer pattern.

9. The method as claimed in claim 1, wherein the seed layer comprises a material substantially the same as that of the conductive bump.

10. The method as claimed in claim 1, wherein the conductive bump comprises gold.

11. The method as claimed in claim 1, wherein forming the conductive bump is performed by an electroplating process.

12. The method as claimed in claim 1, wherein the conductive pad is formed on the substrate by a damascene process.

13. The method as claimed in claim 1, wherein the conductive pad comprises aluminum, titanium, tungsten, platinum, copper, silver, gold or alloys of these materials.

14. The method as claimed in claim 1, wherein the diffusion barrier layer pattern comprises chromium, titanium-tungsten, or nickel.

15. The method as claimed in claim 1, wherein the diffusion barrier layer pattern comprises a multilayer formed from a chromium-copper bilayer, a titanium-tungsten-copper trilayer, or an aluminum-nickel bilayer.

16. The method as claimed in claim 8, wherein no undercut generates in the diffusion barrier layer pattern formed under the photoresist pattern, and the diffusion barrier layer pattern closely seals the sacrificial layer pattern and the anti-reflection layer pattern.

17. A connector structure, comprising:
a substrate;
a conductive pad over the substrate;
an anti-reflective layer pattern over edge portions of the conductive pad;
a diffusion barrier layer pattern over the conductive pad and the anti-reflective layer pattern;
a sacrificial layer pattern separating and being in direct contact with the anti-reflection layer pattern and the diffusion barrier layer pattern such that there is no open space between the anti-reflection layer pattern and the diffusion barrier layer pattern;
a seed layer pattern over the diffusion barrier layer pattern; and
a bump over the seed layer pattern.

18. The connector as claimed in claim 17, wherein the conductive bump comprises gold.

19. The connector as claimed in claim 17, wherein the diffusion barrier layer pattern comprises chromium, titanium-tungsten, or nickel; or the diffusion barrier layer comprises a multilayer formed from a chromium-copper bilayer, a titanium-tungsten-copper trilayer, or an aluminum-nickel bilayer.

20. The connector as claimed in claim 17, wherein the seed layer pattern is a multi-layer comprising a copper-gold bilayer, a copper-palladium bilayer, or a gold-palladium bilayer.
